(19) United States
(12) Patent Application Publication
(10) Pub. No.: US 2019/0212612 A1
(43) Pub. Date: Jul. 11, 2019

(54) COLOR FILTER, COLOR FILM SUBSTRATE, MANUFACTURING METHOD THEREOF AND DISPLAY DEVICE

(71) Applicants: BEIJING BOE DISPLAY TECHNOLOGY CO., LTD., BEIJING (CN); BOE TECHNOLOGY GROUP CO., LTD., BEIJING (CN)

(72) Inventor: Yanqiu LI, Beijing (CN)

(21) Appl. No.: 16/329,007

(22) PCT Filed: Jun. 22, 2018
(86) PCT No.: PCT/CN2018/092301

§ 371 Date: Feb. 27, 2019

(30) Foreign Application Priority Data
Jun. 23, 2017 (CN) 201710488222.6

(51) Int. Cl. G02F 1/1335; G02B 1/00; H01L 27/32; H01L 51/52

(52) U.S. Cl. CPC G02F 1/133555; G02F 1/133516; G02B 1/005; G02F 2001/133614; H01L 51/5271; H01L 51/5281; H01L 27/3244

(57) ABSTRACT

The present disclosure provides a color filter, a color filter substrate, a method of manufacturing the same, and a display device. The color filter comprises a plurality of color filter units, each of the color filter units comprising a plurality of sub-color-filters, each sub-color-filter allowing light of a wavelength range to pass through, and each of the sub-color-filters includes a photonic crystal layer and a photoluminescent material disposed in the photonic crystal layer, wherein light that the photoluminescent material is capable of emitting has a color corresponding to a color of the light which the respective sub-color-filter allows to pass.

### CROSS-REFERENCE TO RELATED APPLICATIONS

The present disclosure claims priority to Chinese Patent Application No. 201710488222.6 filed on Jun. 23, 2017, which is herein incorporated in its entirety by reference.

### FIELD

The present disclosure relates to a color filter, a color filter substrate, a method of manufacturing the same, and a display device.

### BACKGROUND

In the conventional display panel, titanium dioxide quantum dots are generally used to prepare a color filter layer. In the system in which titanium dioxide is used, the different colors are generally achieved by changing the components of CsPbX (X═Cl, Br, I), for example, CsPbBr3 emits green light, CsPbI3 emits red light. However, CsPbX (X═Cl, Br, I) has very limited variable range in size, especially in the strong quantum confinement range of small size (<8 nm). Moreover, a strong backlight is required to achieve the brightness requirement of the display panel, and the light utilization rate is low.

Therefore, there is a need for improved color filter, color filter substrate, method of manufacturing the same, and display device.

### SUMMARY

According to an aspect of the present disclosure, a color filter is provided that comprises a plurality of color filter units, each of the color filter units comprising a plurality of sub-color-filters, each sub-color-filter allowing light of a wavelength range to pass through, and each of the sub-color-filters includes a photonic crystal layer and a photoluminescent material disposed in the photonic crystal layer, wherein light that the photoluminescent material is capable of emitting has a color corresponding to a color of the light which the respective sub-color-filter allows to pass.

In some embodiments, each of the sub-color-filters is provided with a mesoporous material, and the photoluminescent material is loaded to the mesoporous material. In some embodiments, the mesoporous material is mesoporous silica.

In some embodiments, the photoluminescent material comprises the following units: Cs, Pb and X, wherein X is a halogen.

In some embodiments, the photonic crystal layer of each of the sub-color-filters comprises one or more recesses, and the photoluminescent material is disposed in the one or more recesses.

In some embodiments, the color filter further comprises mesoporous material(s) disposed in the one or more recesses, wherein the photoluminescent materials are loaded into the respective mesoporous materials. In some embodiments, the recess does not penetrate through the photonic crystal layer.

In some embodiments, a distance between any two points in the sub-color-filter is not more than 8 nanometers. In some embodiments, each of the color filter units comprises at least three sub-color-filters, the three sub-color-filters allowing light of respective different colors to pass through.

According to another aspect of the present disclosure, a color filter substrate is provided that comprises a color filter of any embodiment of the present disclosure.

According to another aspect of the present disclosure, a display device is provided comprising a color filter of any embodiment of the present disclosure. In some embodiments, the color filter is provided in the color filter substrate.

In some embodiments, the display device further comprises an array substrate, the array substrate is disposed opposite to the color filter substrate, and a side of the array substrate adjacent to the color filter substrate is provided with a reflective layer. In some embodiments, the reflective layer is a semi-reflective layer.

According to a further aspect of the present disclosure, a method is provided that comprises: forming a photonic crystal layer comprising a plurality of photonic crystal units, each of the photonic crystal units comprising a plurality of sub-photonic crystal layers, each photonic crystal layer allowing light of a wavelength range to pass through; etching the photonic crystal layer to form a recess in a sub-photonic crystal layer; providing photoluminescent material in the recess, the photoluminescent material capable of emitting light that has a color corresponding to a color of the light which the sub-photonic crystal layer is allowed to pass through.

In some embodiments, providing photoluminescent material in the recess comprises: providing the photoluminescent material into a mesoporous material; and placing the mesoporous material which is provided with the photoluminescent material in the recess.

In some embodiments, providing photoluminescent material in the recess comprises: providing a mesoporous material in the recess; providing the photoluminescent material into the mesoporous material.

In some embodiments, providing the photoluminescent material into the mesoporous material comprises: immersing the mesoporous material with a solution comprising the photoluminescent material to; and drying and heating the mesoporous material impregnated with the photoluminescent material to form the mesoporous material provided with the photoluminescent material.

In some embodiments, forming the photonic crystal layer comprises: forming the photonic crystal layer on a side of a substrate, wherein the substrate is configured for use as a substrate for a color film substrate. In some embodiments, each of the color filter units comprises at least three sub-color-filters that allow light of respective different colors to pass.

In some embodiments, the photoluminescent material is loaded to the mesoporous material in advance, before providing photoluminescent material in the recess. In some embodiments, the recess does not penetrate through the photonic crystal layer.

### BRIEF DESCRIPTION ON THE DRAWINGS

FIG. 1 is a schematic structural view of a color filter substrate including a color filter in an embodiment of the present disclosure.

FIG. 2 is a schematic structural view of a color filter substrate including a color filter in an embodiment of the present disclosure.

FIG. 3 is a schematic view showing the relationship between the band gap, the particle radius and the composite quantity of the composite material in an embodiment of the present disclosure.

FIG. 4 is a schematic view showing the relationship between the absorbance and the concentration of composite quantity of a composite material in an embodiment of the present disclosure.

FIG. 5 is a schematic structural view of a display device in an embodiment of the present disclosure.

FIG. 6 is a schematic flow chart of preparing a color filter substrate in an embodiment of the present disclosure.

FIG. 7 is a schematic view showing a preparation process of a mesoporous material loaded with a photoluminescent material in an embodiment of the present disclosure.

FIG. 8 is a schematic view showing a structure of a color filter substrate including a color filter in an embodiment of the present disclosure.

FIGS. 9A and 9B illustrate methods of providing a photoluminescent material in a photonic crystal layer in accordance with embodiments of the present disclosure.

### DETAILED DESCRIPTION OF ILLUSTRATIVE EMBODIMENTS

Embodiments of the present disclosure are described in detail below. The embodiments described below are illustrative only, and are used to explain the principles of present disclosure, and shall not be construed as limiting the disclosure. Where specific technique means or conditions are not indicated in the embodiments, they can be carried out on basis of the technique means or conditions described in the literature in the art or in accordance with the product specifications (if any). Those reagents or instruments that are commercially available are not particularly indicated with the manufacturers/providers thereof.

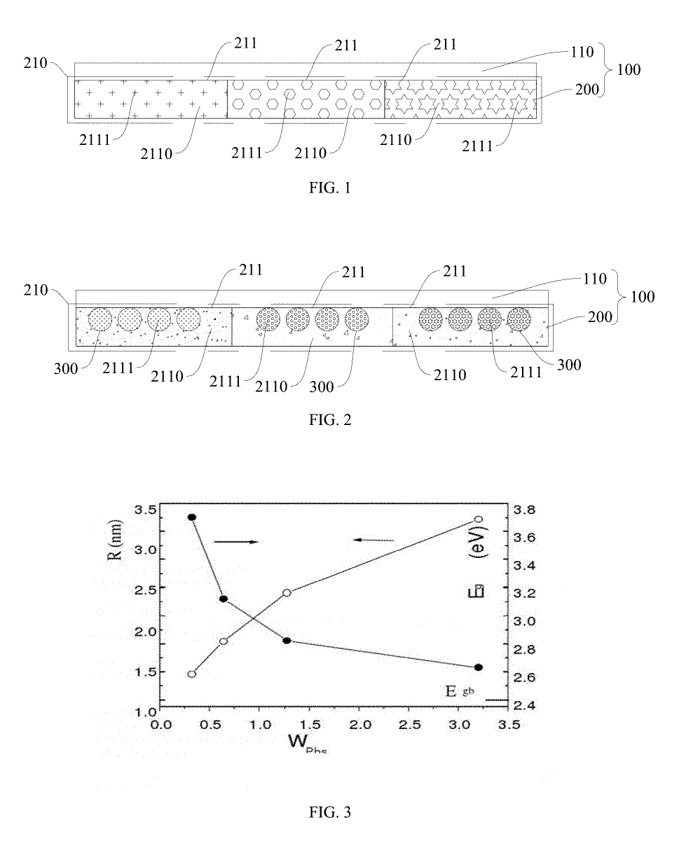

In an aspect of the disclosure, a color film substrate is provided. According to an embodiment of the present disclosure, referring to FIG. 1, the color filter substrate 100 includes a color filter 200. The color filter 200 includes a plurality of color filter units 210. Each of the color filter units 210 includes a plurality of sub-color-filters 211. Each sub-color-filter allows light of a wavelength range (or a color) to pass through. For example, in some embodiments, each of the color filter units includes at least three sub-color-filters that allow light of different colors to pass, respectively. In other embodiments, each of the color filter units may include four or more sub-color-filters, each of which allowing light of a respective color (or respective wavelength range) to pass.

Each of the sub-color-filters includes a photonic crystal layer 2110 and a photoluminescent material 2111 disposed in the photonic crystal layer 2110. The photoluminescent material 2111 corresponds to the color of the sub-color-filter 211. In some embodiments, the photoluminescent material 2111 is configured such that the color of the light that it can emit corresponds to the color of the light that the corresponding sub-color-filter 211 allows to pass.

Thus, by providing a color filter including a photonic crystal layer, and further, a photoluminescent material in the photonic crystal layer, the size of the sub-color-filter can be reduced, and high resolution can be achieved. In addition, in combination with the light that the photonic crystal allows to pass and the light emitted by the photoluminescent material which is excited, the display requirements can be sufficiently satisfied. In particular, by adjusting the amount of the photoluminescent material incorporated, the size of the sub-color-filter can be allowed to be adjusted within a certain range. The more the amount of photoluminescent material is added, the smaller the size of the sub-color-filter is. In addition, with the color filter thus configured, it is possible to filter out light of other colors/wavelengths by the photonic crystal, and to excite the photoluminescent material therein with the light passing through the photonic crystal, thereby light emission can be improved and luminescence efficiency can be effectively improved. In addition, the plurality of sub-color-filters respectively allow light of different respective colors to pass, so that the display performance of the display device can be effectively achieved.

Those skilled in the art would readily understand that in some embodiments, the color filter unit described herein may correspond to a pixel unit in the display panel, and the sub-color-filter may correspond to a sub-pixel unit in the pixel unit. FIG. 1 illustrates a structure of a color filter substrate according to some embodiments of the present disclosure, taking as an example a case where each pixel unit includes three sub-pixel units, and FIG. 1 only shows a schematic sectional view of one color filter unit. The color filter substrate can be arranged with a plurality of color filter units thereon in an array. Of course, the specific structure of the color filter substrate of the present disclosure is not be limited to the case shown in FIG. 1, and reasonable changes and replacements can be made on the basis of the present disclosure and embraced within the scope of the present disclosure, without departing from the inventive concepts of the present disclosure. For example, the color filter unit may include 4, 5 or more sub-color-filters, and the like.

It should be noted that the description “color of the photoluminescence material corresponding to color of the sub-color-filter” or the like used herein means that the color of the light, which is emitted by the photoluminescent material after being excited by light, is consistent with the color of the light allowed, by the sub-color-filter in which the photoluminescent material is located, to pass. That is, the color of the light which is emitted by the photoluminescent material in each sub-color-filter after being excited is consistent with the color of the light which the corresponding photonic crystal is allowed to pass. For example, in a sub-color-filter, the photonic crystal allows red light to pass, and the photoluminescent material disposed in the photonic crystal is also excited to emit red light.

According to an embodiment of the present disclosure, referring to FIG. 1, the color filter substrate may further include a substrate 110. There is no limitation on the material(s) of and method(s) for forming the substrate, and those skilled in the art may select any material(s) and method(s) which can be used for manufacturing the substrate, for example, comprising but not limited to glass substrates and the like, in the art. Thereby, the substrate can support the color filter, and the substrate may have a high transmittance to improve the display performance.

According to an embodiment of the present disclosure, referring to FIG. 2, in order to further reduce the size of the sub-color-filter, a mesoporous material 300 may be disposed in each of the sub-color-filters. Photoluminescent material 2111 is loaded by the mesoporous material 300. Thus, by controlling the pore structure of the mesoporous material, the size of the sub-color-filter can be made more controllable, smaller, and easy to be implemented. In addition, by controlling the pore structure or size of the mesoporous material, the configuration of the photoluminescent material can be further adjusted so that more light is emitted from the sub-filter of the same size, thereby reducing the size of the sub-filter and still meeting the display requirements.

According to an embodiment of the present disclosure, the photoluminescent material may be loaded on the outer surface of the mesoporous material, the inner wall of the pore, the inside of the pore, and the like. There is on limitation on the manner by which the photoluminescent material and the mesoporous material are bonded as long as the photoluminescent material can be loaded to the mesoporous material. Those skilled in the art can flexibly select the bonding manners as needed, for example, physical adsorption, chemical bonding, and the like.

Additionally, the term “mesoporous material” refers to a category of porous materials having a pore aperture between 2 and 50 nm. The mesoporous material can have a very high specific surface area, a regularly ordered pore structure, a narrow pore distribution, and continuously adjustable pore sizes. In the embodiments of the present disclosure, the mesoporous material may have different specific surface areas by controlling the pore structure and the mesoporous radius of the mesoporous material, thereby controlling the amount of photoluminescent material loaded on the mesoporous material, thereby sub-color-filters of different sizes can be achieved. According to an embodiment of the present disclosure, by a photoluminescent material combined with a photonic crystal, a sub-color-filter of a smaller size can be achieved, and the resolution can be improved.

There is no limitation on the mesoporous material that can be employed according to the embodiments of the present disclosure as long as it has a suitable pore structure and does not adversely affect the display function. Those skilled in the art can flexibly select mesoporous materials as needed. In some embodiments of the present disclosure, the mesoporous material that may be employed is mesoporous silica. Thus, the controllability of pores therein can be enhanced, and the mesoporous material is widely sourced, easy to obtain, and low in cost, and has no negative impact on the display function.

There is no limitation on the photoluminescent materials that can be employed according to the embodiments of the present disclosure as long as light of a respective color can be emitted under excitation by light. Those skilled in the art can flexibly select the photoluminescent material as needed. In some embodiments of the present disclosure, the photoluminescent material comprises the following elements: Cs, Pb, X, wherein X is a halogen. For example, the photoluminescent material can be represented as CsPbXy, and in some embodiments of the present disclosure, X is Cl, Br, or I, and y can be 3. Among them, CsPbBr3 emits green light when being excited, CsPbI3 emits red light when being excited, and CsPbCl3 emits blue light when being excited. When the backlight emits white mixed light to the sub-color-filters, the above three photoluminescent materials respectively emit green light, red light, and blue light. The photonic crystals (or photonic crystal layers) corresponding to the photoluminescent materials respectively allow green, red and blue light to pass, and the light of other colors are filtered and reflected back by the photonic crystals. Thereby, the display function can be effectively achieved, and the luminescence efficiency is high. In addition, by combining the mesoporous material with CsPbX (X═Cl, Br, I), the sub-color-filter is more dimensionally controllable and can be made smaller in size. According to the embodiments of the present disclosure, there is no limitation on the specific arrangements of the photoluminescent material in the photonic crystal as long as it can be ensured that the photonic crystal can allow only the light of a specific wavelength to pass through, and that the photoluminescent material can be excited by the light to emit light of a corresponding color; and those skilled in the art can flexibly select the arrangements according to actual needs. In some embodiments of the present disclosure, the photoluminescent material may be uniformly distributed in the photonic crystal. In some embodiments of the present disclosure, a recess may be formed in the photonic crystal and the photoluminescent material can be disposed in the recess. Such an arrangement can use the photonic crystal to filter out light of other colors, and can also excite the photoluminescent material therein by the light passing through the photonic crystal, thereby effectively improving the illumination and improving the luminescence efficiency.

According to an embodiment of the present disclosure, the structure of the photonic crystal, the wavelength of light allowed to pass, and the mesoporous radius of the mesoporous material can be obtained by appropriate calculation and/or experimental verification according to application requirements. In some embodiments of the present disclosure, the structure of the photonic crystal and the mesoporous radius of the mesoporous material can be selected as follows.

The photonic crystal band gap can be obtained by solving the Maxwell equation by the plane wave expansion method. Using the magnetic field H, the Maxwell equation becomes formula (1):

$$∇ \times [ \frac{1}{s ( r )} ∇ \times H ] = \frac{{ω}^{2}}{{c}^{2}} H ,$$

where ε(r) is dielectric constant, ω is frequency, c is light speed in the vacuum. And in the case that H and ε(r) are developed by plane waves, following equations are obtained.

$$\begin{matrix}H ( r ) = {\sum }_{G} {\sum }_{j = 1 , 2}^{ } {H}_{G , j} {e}_{j} {e}^{i ( k + G ) \cdot r} , & equation ( 2 ) \\ ɛ ( r ) = {\sum }_{G} ɛ ( G ) {e}^{i G \cdot r} , & equation ( 3 )\end{matrix}$$

where k is first Brillouin zone wave vector, G is reciprocal lattice vector, and eⱼ(j=1, 2) is a unit vector perpendicular to (k+G). The Fourier expansion coefficient ε(G) is the formula (4):

$$ɛ ( G ) = \frac{1}{S} {\int }_{S} ɛ ( r ) {e}^{- iG \cdot r} dr ,$$

The above integral formula (4) is performed in a primitive cell S, and equations (2) and (3) are substituted into equation (1) to obtain two eigenfunctions. The eigenequation corresponding to E polarization (the electric field being parallel to the air column) is the formula (5):

$${\sum }_{G} \vert k + G \vert \vert k + {G}^{′} \vert {ɛ}^{- 1} ( G - {G}^{′} ) {H}_{{G}^{′} .1} = \frac{{ω}^{2}}{{c}^{2}} {H}_{G .1} ;$$

The eigenequation corresponding to H polarization (the magnetic field being parallel to the air column) is equation (6):

$${\sum }_{G} [ k + G ] [ k + {G}^{′} ] {ɛ}^{- 1} ( G - {G}^{′} ) {H}_{{G}^{′} .2} = \frac{{ω}^{2}}{{c}^{2}} {H}_{G .2} ;$$

where ε⁻¹(G-G′) is the inverse of the matrix ε(G-G′). A fill ratio f=Sr/S (Sr is the cross-sectional area of the air column in the primitive cell) and a geometric factor I(G) are introduced, the geometric factor I(G) defined as formula (7):

$$I ( G ) = \frac{1}{S} {\int }_{{S}_{r}} {e}^{- G \cdot r} dr . ,$$

Equation (4) can be simplified to equation (8):

$$ɛ ( G ) = \{ \begin{matrix}{ɛ}_{b} + f ( {ɛ}_{a} - {ɛ}_{b} ) , & G = 0 ; \\ ( {ɛ}_{a} - {ɛ}_{b} ) I ( G ) , & G \neq 0.\end{matrix}$$

where εₐ is the dielectric constant of the air column and ε_{b} is the dielectric constant of the background.

Through the above calculation, the structure of the two-dimensional photonic crystal can be selected as needed.

According to formula (9)

$$Eg = Egb + \frac{{ϕ}^{2} {π}^{2}}{2 μ {R}^{2}} - \frac{1.8 {e}^{2}}{ϵ R} ,$$

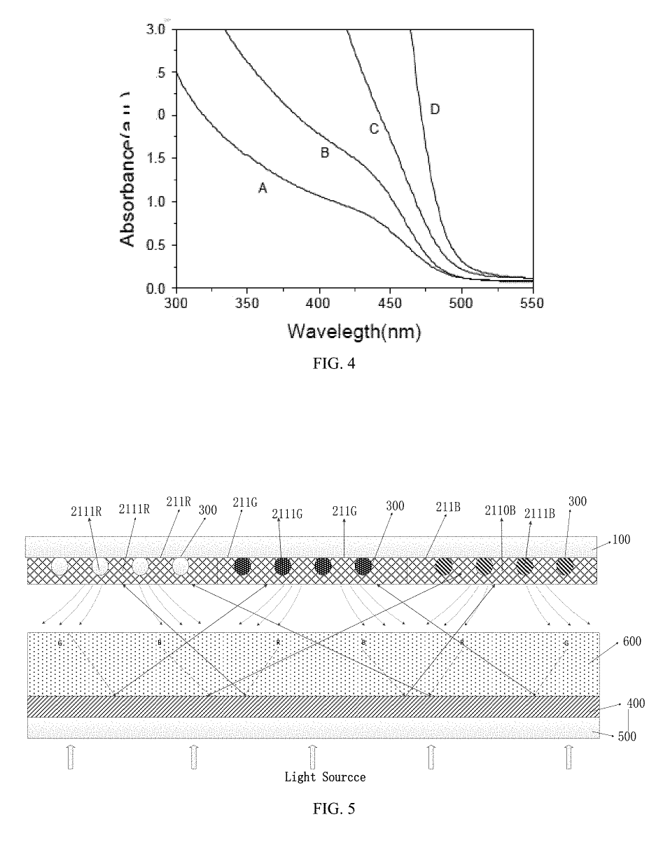

the band gap Eg of the nanoparticles is related to the particle radius R; Egb is the energy gap of the semiconductor bulk; μ is the reduced mass of electrons and holes; and ε is dielectric constant. The third term in the formula is the Coulomb interaction energy of the electron-hole pair, and the Coulomb interaction energy is omitted. Mesoporous silica and CsPbX (X═Cl, Br, I) composite has a particle size comparable to the free exciton Bohr radius (about 2 nm) thereof, thus the quantum confinement effect is significant, and the absorption side blue shift is large. As can be seen from FIG. 3, for a same composite quantity W, the smaller the particle size R (nm) of mesoporous silica and CsPbX (x=Cl, Br, I) composite is, the wider the band gap Eg (eV) is. According to the above formulas, the size of the desired SiO₂ mesopores can be calculated, and the size of the composite particles is inversely proportional to the band gap as the composite quantity increases. When the composite quantities for mesoporous silica and CsPbX (X═Cl, Br, I) composites are different, as shown in FIG. 4 where the composite quantities A<B<C<D, it can be seen that as the composite quantity of mesoporous silica and CsPbX (X═Cl, Br, I) composite increases, the absorption edge is red-shifted.

A specific structure of the color filter substrate of the present disclosure will be described in detail below by taking the case of the three primary colors as an example. Specifically, according to a specific embodiment of the present disclosure, referring to FIG. 8, each color filter unit includes three sub-color-filters 211R, 211G, and 211B, which respectively correspond to R, G, and B sub-pixels. The photonic crystal 2110 corresponding to the above three sub-filters also comprises three photonic crystals, namely, 2110R, 2110G, and 2110B, allowing red, green, and blue light to pass, respectively. Photonic crystals 2110R, 2110G, and 2110B can be viewed as three portions of the photonic crystal layer 2110. The photonic crystals 2110R, 2110G, and 2110B respectively have photoluminescence materials 2111R, 2111G, and 2111B which emit red, green, and blue light under excitation of light, respectively. Thereby, the three sub-color-filters 211R, 211G, and 211B can pass red light, green light, and blue light, respectively, to effectively realize the three primary color display.

According to the embodiments of the present disclosure, the arrangements of the sub-color-filters shall not be limited to the arrangement shown in FIG. 8, and those skilled in the art can flexibly select the arrangements according to actual applications. In some embodiments of the present disclosure, the arrange order may be 211G, 211B, 211R, or may be 211G, 211R, 211B, and the like.

According to the embodiment of the present disclosure, there is no limitation on the shape and size of the sub-color-filter, and those skilled in the art can flexibly select the shape and size according to actual applications. In some embodiments of the present disclosure, the shape of the sub-color-filter includes, but is not limited to, a circle, a rectangle, a square, or other regular or regular shape, and the like. In some embodiments, the distance between any two points of the sub-color-filter with various shapes is not greater than 8 nanometers. In a preferred embodiment of the present disclosure, the sub-color-filter is circular and has a diameter of no more than 8 nanometers. According to an embodiment of the present disclosure, a small-size sub-color-filter can be efficiently achieved, and resolution can be improved.

In another aspect of the disclosure, a display device is provided. According to an embodiment of the present disclosure, the display device includes the color film substrate as described above. Since the color film substrate as described above is used, a sub-color-filter of a smaller size can be achieved, whereby the resolution can be remarkably improved. In addition, by the combination of the photonic crystal and the photoluminescent material, the light utilization efficiency and luminescence efficiency can be improved. It will be appreciated by those skilled in the art that the display device has all the features and advantages of the color film substrate described above, and thus these features and advantages will not be further described herein.

According to an embodiment of the present disclosure, referring to FIG. 5, the display device further includes an array substrate 500 disposed opposite to the color filter substrate 100. A reflective layer 400 is disposed on a side of the array substrate 500 which is close to the color filter substrate 100. Thereby, the light that is filtered out by a photonic crystal corresponding to a sub-color-filter can be reflected back by the reflective layer, and the light of colors of the reflected light pass through the respective photonic crystals of the other two sub-color-filters, thereby significantly improving the utilization of light, and the intensity of the backlight can be accordingly reduced to save costs.

According to an embodiment of the present disclosure, referring to FIG. 5, the display device further includes a functional layer 600. Specifically, the functional layer 600 may be a liquid crystal layer or an organic light-emitting layer. There is no limitation on the liquid crystal layer material, the organic light-emitting layer material, the methods for forming the same, and the like, and the liquid crystal layer and the organic light-emitting layer can be achieved by those skilled in the art using conventional techniques in the art. Thereby, the display function of the display device can be achieved.

According to an embodiment of the present disclosure, there is no limitation on the specific material forming the reflective layer as long as it has a reflection function. In some embodiments of the present disclosure, the material of the reflective layer can be a metal or an all-dielectric. Thus, the reflective layer can be provided with a wide range of materials and with low cost. According to the embodiment of the present disclosure, there is no limitation on the specific method of forming the reflective layer, and the person skilled in the art can flexibly select the method according to actual needs. In some embodiments of the present disclosure, methods of forming the reflective layer comprise, but are not limited to, coating, deposition, printing, or the like. Thus, the process is simple and easy to implement. According to an embodiment of the present disclosure, the reflective layer may be a semi-reflective layer. Therefore, it has a certain transmittance and reflectance, and the light utilization efficiency can be further improved under the premise of ensuring the display function.

According to an embodiment of the present disclosure, there is no limitation on the types of the display device, and the display may be any device or device having a display function in the art, for example, comprise but be not limited to: mobile phone, tablet computer, computer display, game machine, television set, display screens, wearable devices, and other living appliances or household appliances with display functions.

Of course, those skilled in the art would understand that the display device of the present disclosure may include other structures and components possessed by a conventional display device, in addition to the color film substrate and the array substrate as described above. Taking a mobile phone as an example, in addition to the color film substrate and the array substrate of the present disclosure, it may also have other structure(s) and component(s), such as, a touch screen, a casing, a CPU, a camera module, a fingerprint recognition module, a sound processing system, or the like.

In yet another aspect of the present disclosure, a preparation method is provided. According to some embodiments of the present disclosure, the method can be used to prepare a color filter. In other embodiments, the method can also be used to prepare a color film substrate. Referring to FIG. 6, the method may include the following steps.

Step S100: forming a photonic crystal layer.

According to an embodiment of the present disclosure, the photonic crystal layer includes a plurality of photonic crystal units, each photonic crystal unit including a plurality of sub-photonic crystal layers, the plurality of sub-photonic crystal layers respectively allowing light of different colors to pass.

According to the embodiment of the present disclosure, the types and forms of the photonic crystal layer are not particularly limited, and can be flexibly selected by those skilled in the art according to actual needs. In some embodiments of the present disclosure, the photonic crystal may be a one-dimensional photonic crystal, a two-dimensional photonic crystal, and a three-dimensional photonic crystal. As a result, the source thereof is wide and the cost is low.

It should be noted that the photonic crystal unit described herein may correspond to a pixel unit in the display panel. The sub-photonic crystal layer may correspond to a sub-pixel unit in a pixel unit. A plurality of photonic crystal units may be arrayed on the color filter substrate. Each photonic crystal unit may include a plurality of sub-photonic crystal layers, such as three, four, five, etc. sub-photonic crystal layers. The colors of the light that is allowed to pass through the plurality of sub-photonic crystal layers in each photonic crystal unit are not particularly limited as long as the display function can be effectively achieved, and for example, the display may be achieved in RGB, RGBW, RGBYW or the like.

Step S200: etching the photonic crystal layer to form a recess in the sub-photonic crystal layer.

According to some embodiments of the present disclosure, the photonic crystal layer may be partially etched, that is, the recess formed by the etching does not penetrate through the photonic crystal layer. In some embodiments of the present disclosure, the photonic crystal layer is half etched. Thereby, a recess in which the photoluminescent material is to be placed can be formed. In this way, the position, shape, size and the like of the photoluminescent material can be controlled relatively accurately, so that the functionality of the photoluminescent material is controllable. According to this embodiment, not only the sub-photonic crystal layer can be used to filter out light of other color wavelengths, but also the photo-emitting material disposed in the recess can be excited by the light passing through the photonic crystal, effectively improving the luminescence efficiency. According to some embodiments of the present disclosure, the recess may be a portion of a circle or a circle; in other embodiments, the recess may also have other shapes. According to the embodiments of the present disclosure, there is no special requirement for the etching method, and those skilled in the art can select the etching method(s) commonly used in the art.

Step S300: providing a photoluminescent material in the recess, the photoluminescent material corresponding to the color of the sub-photonic crystal layer. In other words, the color of the light that the photoluminescent material is capable of emitting corresponds to the color of the light that the corresponding sub-photonic crystal layer is allowed to pass.

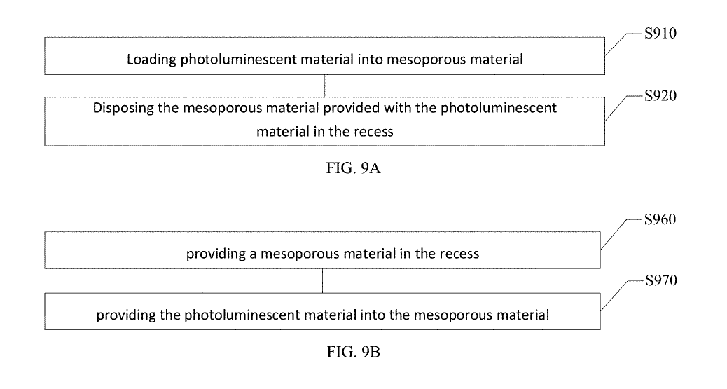

According to an embodiment of the present disclosure, the manners of providing the photoluminescence in the recess are not particularly limited. For example, the photoluminescent material can be placed directly in the recess, or the photoluminescent material can be placed in the recess indirectly by use of other materials. In a preferred embodiment of the present disclosure, as shown in FIG. 9A, in step S910 the photoluminescent material may be loaded or provided into the mesoporous material in advance, and in step S920, the mesoporous material provided with the photoluminescent material is disposed in the recess, that is, a composite material formed of a mesoporous material and a photoluminescent material is disposed in the recess. Thereby, it is possible to reduce the size of the sub-photonic crystal layer while still satisfying the requirements for display quality. In this way, the size of the sub-photonic crystal layer can be better regulated, the size can be reduced, the resolution can be improved, the luminescence efficiency can be greatly improved, the brightness of the backlight can be reduced, and/or the energy consumption can be reduced.

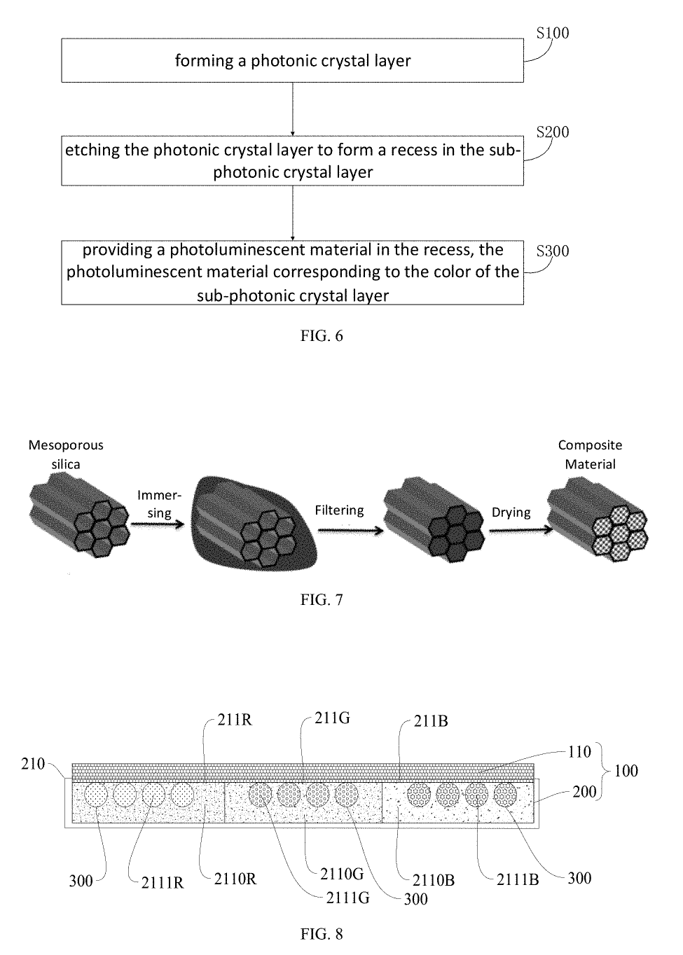

There is no limitation on the methods for loading or providing the photoluminescent material to the mesoporous material according to the embodiments of the present disclosure, and those skilled in the art can flexibly select the methods as needed. In some embodiments of the present disclosure, referring to FIG. 7, the photoluminescent material can be loaded or provided to the mesoporous material by: immersing the mesoporous material with a solution containing the photoluminescent material; and then optionally, removing excess solution containing the photoluminescent material; followed by drying and heating treatment to obtain a mesoporous material loaded with a photoluminescent material. Excess solution containing the photoluminescent material can be removed by filtration. Drying can be carried out by vacuum drying. The temperature of the heating treatment may be from 100° C. to 200° C. As such, particles of the composite of the photoluminescent material and the mesoporous material can be formed.

In other embodiments, providing the photoluminescent material in the recess of the photonic crystal layer can be performed as follows. A mesoporous material is provided in the recess. A photoluminescent material is then provided into the mesoporous material. For example, the mesoporous material is immersed with a solution containing the photoluminescent material. Thereafter, similarly, drying and heating can be carried out. In this case, the filtration step shown in FIG. 7 can be omitted.

According to the embodiments of the present disclosure, the process is simple and convenient, the conditions are mild, it is easy to implement, the cost is low, and/or the luminous effect and the luminescence efficiency are ideal.

According to the embodiments of the present disclosure, the photonic crystal, the photoluminescent material, the mesoporous material, and the like involved in the method of preparing the color filter substrate are all the same as those described above in association with the color film substrates, and will not be further described herein.

According to the embodiments of the present disclosure, the methods for preparing a color filter substrate are simple and quick, mature, and easy to be industrialized, and can effectively prepare the color film substrate as described above, and the prepared color film substrate has such advantages such as small size, high resolution, and high utilization of light.

In addition, those skilled in the art would understand that, in addition to the steps of forming a color filter as described above, the method for preparing a color filter substrate may further include other preparation steps for preparing a conventional color filter substrate, such as a step of forming a black matrix, a step of forming a photo-resist layer (or a planarization layer) or the like. These other steps can be performed by those skilled in the art in accordance with conventional procedures.

In the description of the present specification, the description with reference to the terms “an embodiment”, “some embodiments”, “example(s)”, “specific example(s)”, or “some examples” and the like means specific feature, structure, material, or characteristic described in connection with the embodiment(s) or example(s) is included in at least one embodiment or example of the present disclosure. In the present specification, the schematic representation of the above terms is not necessarily directed to the same embodiment(s) or example(s). Furthermore, the specific features, structures, materials, or characteristics described may be combined when suitable in any one or more embodiments or examples. In addition, various embodiments or examples described in the specification, as well as features of the various embodiments or examples, may be combined.

While the embodiments of the present disclosure have been shown and described above, it is to be understood that the foregoing embodiments are merely illustrative and are not to be construed as limiting the scope of the present disclosure. Variations, modifications, substitutions and variations can be made by those with ordinary sills in the art without departing the spirit and scope of the present disclosure.

The present disclosure claims priority to Chinese Patent Application No. 201710488222.6 filed on Jun. 23, 2017, the entire content of which is incorporated herein by reference.

1. A color filter comprising a plurality of color filter units, each of the color filter units comprising a plurality of sub-color-filters, each sub-color-filter allowing light of a wavelength range to pass through, and each of the sub-color-filters including a photonic crystal layer and a photoluminescent material disposed in the photonic crystal layer,
wherein light that the photoluminescent material is capable of emitting has a color corresponding to a color of the light which the sub-color-filter corresponding to the photoluminescent material allows to pass.

2. The color filter according to claim 1, wherein each of the sub-color-filters is provided with a mesoporous material, and the photoluminescent material is loaded to the mesoporous material.

3. The color filter according to claim 2, wherein the mesoporous material is mesoporous silica.

4. The color filter according to claim 1, wherein the photoluminescent material comprises the following units: Cs, Pb and X, wherein X is a halogen.

5. The color filter of claim 1, wherein in each of the sub-color-filters, the photonic crystal layer comprises at least one recess, and the photoluminescent material is disposed in the at least one recess.

6. The color filter of claim 5 further comprising mesoporous materials disposed in the recesses of the respective photonic crystal layers, wherein the photoluminescent materials are loaded into the respective mesoporous materials.

7. The color filter of claim 5, wherein the at least one recess does not penetrate through the photonic crystal layer.

8. The color filter according to claim 5, wherein each of the color filter units comprises at least three sub-color-filters, the three sub-color-filters allowing light of respective different colors to pass through.

9. The color filter according to claim 1, wherein a distance between any two points in the sub-color-filter is not more than 8 nanometers.

10. A display device comprising a color filter substrate, the color filter substrate comprising the color filter of claim 1.

11. The display device according to claim 10, further comprising an array substrate, the array substrate is disposed opposite to the color filter substrate, and a side of the array substrate adjacent to the color filter substrate is provided with a reflective layer.

12. The display device of claim 11, wherein the reflective layer is a semi-reflective layer.

13. A method comprising:
forming a photonic crystal layer comprising a plurality of photonic crystal units, each of the photonic crystal units comprising a plurality of sub-photonic crystal layers, each photonic crystal layer allowing light of a wavelength range to pass through;
etching the photonic crystal layer to form a recess in a sub-photonic crystal layer;
providing photoluminescent material in the recess, the photoluminescent material capable of emitting light that has a color corresponding to a color of the light which the sub-photonic crystal layer is allowed to pass through.

14. The method of claim 13, wherein providing photoluminescent material in the recess comprises:
providing the photoluminescent material into a mesoporous material; and
placing the mesoporous material which is provided with the photoluminescent material in the recess.

15. The method of claim 13, wherein providing photoluminescent material in the recess comprises:
providing a mesoporous material in the recess;
providing the photoluminescent material into the mesoporous material.

16. The method according to claim 14, wherein providing the photoluminescent material into the mesoporous material comprises:
immersing the mesoporous material with a solution comprising the photoluminescent material to; and
drying and heating the mesoporous material impregnated with the photoluminescent material to form the mesoporous material provided with the photoluminescent material.

17. The method of claim 13, wherein forming the photonic crystal layer comprises:
forming the photonic crystal layer on a side of a substrate,
wherein the substrate is configured for use as a substrate for a color film substrate.

18. The method of claim 13, wherein the recess does not penetrate through the photonic crystal layer.

19. The method of claim 13, wherein each of the color filter units comprises at least three sub-color-filters that allow light of respective different colors to pass.

20. The method according to claim 15, wherein providing the photoluminescent material into the mesoporous material comprises:
immersing the mesoporous material with a solution comprising the photoluminescent material to; and
drying and heating the mesoporous material impregnated with the photoluminescent material to form the mesoporous material provided with the photoluminescent material.
